(19) United States
(12) Patent Application Publication
(10) Pub. No.: US 2025/0335672 A1
(43) Pub. Date: Oct. 30, 2025

(54) SYSTEM AND METHOD UTILIZING MACHINE LEARNING (ML) DATA SEGREGATION TO OPTIMIZE PRESSURE-VOLUME-TEMPERATURE (PVT) -BASED RESERVOIR FLUID CHARACTERIZATION TECHNIQUES

(71) Applicant: Saudi Arabian Oil Company, Dhahran (SA)

(72) Inventors: Somiari Bestman Bestman, Dhahran (SA); Rasheed M. Almahdi, Dhahran (SA); Mohammed K. Alammari, Dhahran (SA)

(21) Appl. No.: 18/649,895

(22) Filed: Apr. 29, 2024

(51) Int. Cl. G06F 30/28

(52) U.S. Cl. CPC G06F 30/28

(57) ABSTRACT

A method includes: accessing a first dataset comprising: (i) a first plurality of records of compositional measurements, and (ii) a data structure encoding a plurality of thermodynamic models developed using pressure-volume-temperature (PVT) data; accessing a second dataset comprising a second plurality of records of compositional measurements; analyzing the first plurality of records to generate a plurality of clusters; classifying the second plurality of records into one or more clusters generated from the first plurality of records; driving a thermodynamic model from the plurality of thermodynamic models that corresponds to a given cluster to determine a fluid property of portions of the hydrocarbon fluid samples that correspond to portions of the second plurality of records classified into the given cluster; and presenting a rendering of the fluid property as time elapses and additional records become available from the second dataset.

### TECHNICAL FIELD

This disclosure generally relates to reservoir characterization in the context of geo-exploration for oil and gas.

### BACKGROUND

Petroleum generally is composed of a complex mixture of hydrocarbons of various molecular weights, plus other organic compounds. The exact molecular composition of petroleum varies widely from formation to formation. The proportion of hydrocarbons in the mixture is highly variable and ranges from as much as 97% by weight in the lighter oils to as little as 50% in the heavier oils and bitumens. The hydrocarbons in petroleum are mostly alkanes (linear or branched), cycloalkanes, aromatic hydrocarbons, or more complicated chemicals like asphaltenes. The other organic compounds in petroleum typically contain carbon dioxide (CO₂), nitrogen, oxygen, and sulfur, and trace amounts of metals such as iron, nickel, copper, and vanadium.

### SUMMARY

In one aspect, some implementations provide a computer-implemented method including: accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements; accessing a second dataset comprising a second plurality of records of compositional measurements for hydrocarbon fluid samples obtained from a second set of locations at the reservoir; analyzing, using a machine learning module, the first plurality of records of compositional measurements to generate a plurality of clusters; classifying, using the machine learning module, the second plurality of records of compositional measurements into one or more clusters from the plurality of clusters; driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and presenting a rendering of the fluid property as the second dataset expands.

Implementations may include one or more of the following features.

The rendering may be presented iteratively with each update of additional records from the second dataset. The plurality of thermodynamic models may include at least one equation of state (EoS) model. The fluid property may include at least one of: a fluid type, a gravity measure of an underlying hydrocarbon fluid sample, a gas-oil ratio (GOR), or a formation volume factor (Bo). The fluid type may include one of: oil, gas, or condensate. The gravity measure may include the American Petroleum Institute (API) gravity. The machine learning module may launch a KMeans algorithm to generate the plurality of clusters. The machine learning module may launch a decision tree algorithm to classify the second plurality of records of compositional measurements into the one or more clusters. The first set of locations and the second set of locations may not be identical.

In another aspect, some implementations provide one or more computer-readable storage media encoded with instructions that, when executed by one or more computers, cause the one or more computers to perform operations of: accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements; accessing a second dataset comprising a second plurality of records of compositional measurements for hydrocarbon fluid samples obtained from a second set of locations at the reservoir; analyzing, using a machine learning module, the first plurality of records of compositional measurements to generate a plurality of clusters; classifying, using the machine learning module, the second plurality of records of compositional measurements into one or more clusters from the plurality of clusters; driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and presenting a rendering of the fluid property as the second dataset expands.

Implementations may include one or more of the following features.

The rendering may be presented iteratively with each update of additional records from the second dataset. The plurality of thermodynamic models may include at least one equation of state (EoS) model. The fluid property may include at least one of: a fluid type, a gravity measure of an underlying hydrocarbon fluid sample, a gas-oil ratio (GOR), or a formation volume factor (Bo). The fluid type may include one of: oil, gas, or condensate. The gravity measure may include the American Petroleum Institute (API) gravity. The machine learning module may launch a KMeans algorithm to generate the plurality of clusters. The machine learning module may launch a decision tree algorithm to classify the second plurality of records of compositional measurements into the one or more clusters. The first set of locations and the second set of locations may not be identical.

In yet another aspect, some implementations provide a computer system comprising one or more computer processors configured to perform operations of: accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements; accessing a second dataset comprising a second plurality of records of compositional measurements for hydrocarbon fluid samples obtained from a second set of locations at the reservoir; analyzing, using a machine learning module, the first plurality of records of compositional measurements to generate a plurality of clusters; classifying, using the machine learning module, the second plurality of records of compositional measurements into one or more clusters from the plurality of clusters; driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and presenting a rendering of the fluid property as the second dataset expands.

Implementations may include one or more of the following features.

The rendering may be presented iteratively with each update of additional records from the second dataset. The plurality of thermodynamic models may include at least one equation of state (EoS) model. The fluid property may include at least one of: a fluid type, a gravity measure of an underlying hydrocarbon fluid sample, a gas-oil ratio (GOR), or a formation volume factor (Bo). The fluid type may include one of: oil, gas, or condensate. The gravity measure may include the American Petroleum Institute (API) gravity. The machine learning module may launch a KMeans algorithm to generate the plurality of clusters. The machine learning module may launch a decision tree algorithm to classify the second plurality of records of compositional measurements into the one or more clusters. The first set of locations and the second set of locations may not be identical.

Implementations according to the present disclosure may be realized in computer implemented methods, hardware computing systems, and tangible computer readable media. For example, a system of one or more computers can be configured to perform particular actions by virtue of having software, firmware, hardware, or a combination of them installed on the system that in operation causes or cause the system to perform the actions. One or more computer programs can be configured to perform particular actions by virtue of including instructions that, when executed by data processing apparatus, cause the apparatus to perform the actions.

The subject matter described in this specification can be implemented in particular embodiments so as to realize one or more of the following advantages. First, some implementations provide more vivid depiction for lab measurements of hydrocarbon fluid samples with no previous developed EoS models by leveraging machine learning (ML) techniques that cluster/classify the hydrocarbon fluid samples with earlier acquired PVT data based on which EoS models have been developed to allow for computation for a wide array of properties of the petroleum fluid of the reservoir. In large reservoirs where hydrocarbon fluid samples become available in piece meal after production has commenced, continued monitoring and prediction of production can be technically challenging. Using techniques presented in the present disclosure, implementations can provide more vivid monitoring and prediction of reservoir production by leveraging existing EoS models built from previously measured PVT data, thereby generating a more realistic rendering of production course. The salient features are similar to improved computerized animation as a computer-related technology. Second, the data-driven computational aspects entail voluminous data obtained from a vast geophysical exploration site. The amount of data and the depth of data analysis are not practical in the human mind, especially given the streaming nature where new data can become available continuously. On this note, however, the implementations are not limited by, for example, the size of measurement data at the geophysical site. In fact, the technical improvements scale up with the size of data at the geophysical exploration site. This scale-up aspect is another hallmark of the technical improvement directed to the underlying computer-related technology, namely, reservoir monitoring and prediction.

The details of one or more implementations of the subject matter of this specification are set forth in the description, the claims, and the accompanying drawings. Other features, aspects, and advantages of the subject matter will become apparent from the description, the claims, and the accompanying drawings.

### DESCRIPTION OF DRAWINGS

FIG. 1 illustrates an example of clustering a dataset including compositional measurements according to some implementations of the present disclosure.

FIG. 2 illustrates another example of clustering a dataset including compositional measurements according to some implementations of the present disclosure.

FIG. 3 is a chart illustrating an example of cross-correlating features from the compositional measurements, as used by some implementations of the present disclosure.

FIG. 4 is matrix illustrating an example of the correlation coefficients between various features from the compositional measurements, as used by some implementations of the present disclosure.

FIG. 5 shows an example of a flow chart according to some implementations of the present disclosure.

FIG. 6 is a block diagram illustrating an example of hydrocarbon production operations that include field operations and computational operations, according to an implementation of the present disclosure.

FIG. 7 is another block diagram illustrating an example of a computer system used to provide computational functionalities associated with described algorithms, methods, functions, processes, flows, and procedures, according to an implementation of the present disclosure.

Like reference numbers and designations in the various drawings indicate like elements.

### DETAILED DESCRIPTION

The disclosure is directed to utilizing machine learning (ML) segregation techniques to optimize the pressure-volume-temperature (PVT) based reservoir fluid characterization process. For example, some implementations may apply ML methodology to a parent dataset for the purpose of segregation including clustering and classification. The parent dataset refers to a complete dataset from existing PVT characterization techniques and includes multiple data records from a formation, from a field, and from a region that encode results from compositional analysis, constant composition experiment (CCE) and constant volume depletion (CVD) tests. Using these test results, one or more equation of state (EoS) models can be built to fully characterize the underlying data records (e.g., compositional measurements) in terms of predicting reservoir (e.g., fluid behavior). The segregation algorithm can cluster and/or classify the parent dataset. In these implementations, additional datasets (also known as children datasets, or child dataset, which may not be as detailed as the parent data, and may cover different locations in the same reservoir) are also imported. These implementations may then predict the characteristics of the underlying samples associated with the new dataset acquired from the same reservoir as the parent dataset based on results of clustering/classification. For example, through the techniques of cluster/classification for features such as concentration of molecules, dryness/wetness of carbonate fluid samples, balance and character ratios of carbonate fluids, the characteristics of various samples can be segregated to reflect connection to a certain reservoir, field or region. Once a relationship has been established between the new dataset and its equivalent parent, as revealed by the segregation techniques, the EoS model from the parent cluster can be applied to the composition data from the new dataset. In this manner, the EoS model from existing dataset can be used to compute fluid properties of interest based on compositional measurements from the new dataset. The computed fluid properties can be rendered and refreshed to reflect the underlying dataset, which is evolving as field operations unfold.

For context, equation of state (EoS) modeling operates on pressure-volume-temperature (PVT) data, e.g., measured during drilling operations measured after lab testing of samples taken after drilling), and in view of fluid compositional data to reveal properties of the underlying hydrocarbon fluid, which are significant in the oil and gas industry. For example, the fluid properties can be instrumental for calculating the amount of the hydrocarbons initially in place, for reservoir simulation and production forecasting as well as for well, completion, pipeline and surface facility design. For measuring hydrocarbon fluid properties, the pressure-volume-temperature (PVT) properties are generally measured as a function of pressure. This PVT data may be acquired at different location of the production system: e.g., well bottom hole, well tubing head, and at the outlet of the last separator stage. While the PVT data is acquired, hydrocarbon fluid samples may be sent to the laboratory for compositional analysis where the fluid properties are measured. Based on the PVT data acquired from the field, and the laboratory measurements of hydrocarbon fluid samples taken from the field where the PVT data are acquired, a thermodynamic model is typically used, such as an equation of state (EoS) model that represents the phase behavior of the petroleum fluid in the reservoir and is used to predict the hydrocarbon fluid properties under the expected range of pressure and temperature covering the life of the reservoir and the whole production system. Once the EoS model is defined, the EoS model can be used to compute a wide array of properties of the petroleum fluid of the reservoir, such as gas-oil ratio (GOR) or condensate-gas ratio (CGR) (where GOR is the inverse as CGR), density of each phase, volumetric factors and compressibility, and heat capacity and saturation pressure (bubble or dew point). Thus, the EoS model can be solved to obtain saturation pressure at a given reservoir temperature. Moreover, GOR, CGR, phase densities, and volumetric factors are byproducts of the EoS model. Other properties, such as heat capacity or viscosity, can also be derived in conjunction with the information regarding fluid composition. Furthermore, the EoS model can be extended with other reservoir evaluation techniques for compositional simulation of flow and production behavior of the petroleum fluid of the reservoir.

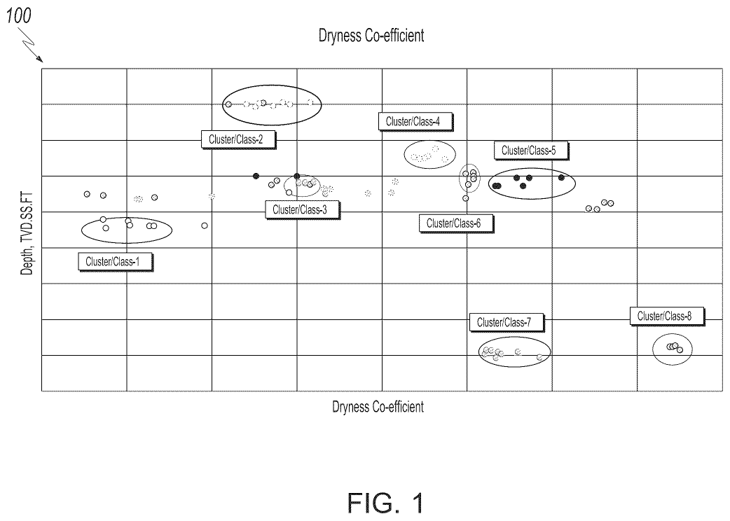

Significantly, the implementations improve reservoir modelling technology by providing, for example, more vivid depiction for lab measurements of hydrocarbon fluid samples with no previous developed EoS models by leveraging machine learning (ML) techniques that cluster/classify the hydrocarbon fluid samples with earlier acquired PVT data based on which EoS models have been developed to allow for computation for a wide array of properties of the petroleum fluid of the reservoir. Such properties include, for example, gas-oil ratio (GOR) or condensate-gas ratio (CGR), density of each phase, volumetric factors and compressibility, and heat capacity and saturation pressure (bubble or dew point), all of which are germane in monitoring and predicting reservoir performance. In large reservoirs where hydrocarbon fluid samples become available in piece meal after production has commenced, continued monitoring and prediction of production can be technically challenging. Using techniques presented in the present disclosure, implementations can provide more vivid monitoring and prediction of reservoir production by leveraging existing EoS models built from previously measured PVT data, thereby generating a more realistic rendering of production course. The salient features are similar to improved computerized animation as a computer-related technology. Moreover, the data-driven computational aspects entail voluminous data obtained from a vast geophysical exploration site. The amount of data and the depth of data analysis are not practical in the human mind, especially given the streaming nature where new data can become available continuously. On this note, however, the implementations are not limited by, for example, the size of measurement data at the geophysical site. In fact, the technical improvements scale up with the size of data at the geophysical exploration site. This scale-up aspect is another hallmark of the technical improvement directed to the underlying computer-related technology, namely, reservoir monitoring and prediction. More details are provided below, in association with FIGS. 1-7.

### Glossary of Terms

Geology and Geophysics Data can be collected from the field seismic survey. Collected seismic field data can be input into the workflow where the data can be analyzed and interpreted to derive geological structures, rock typing, and reservoir features (including fractures, faults, and unconformity) of the reservoir. As the seismic data has the capability of capturing only large features in the field or the reservoir, localized geological features may be missed, such as fractures, faults, and unconformity. Based on the shape of the reservoirs, structural maps (for example, contour maps) can be generated by using depth scales. By using contour maps along with seismic interpretation, rock typing can be determined. Reservoir structures as interpreted from seismic data can be incorporated in numerical models if structural contour maps are available from seismic data.

An Operational Platform can serve as a computer-aided enabler in performing specific operations on a sector model that is regarded as an operational platform. Such a platform can execute requests for visualization of, and computational operations on, uploaded models. The operational platform can also display input parameters and field data, compute model outputs, and compare model outputs to field data. The operational platform can also have the capability of simplifying well trajectories, production data, and injection data to reduce the computational burden. Manipulation of grids, including upscaling and refining as needed, can also be performed on sector models.

Petrophysics can refer to reservoir properties (for example, permeability, porosity, saturations, and pay thickness) originating from petrophysical log data to build static geological models. Petrophysical logs can be built during the drilling phase of the well. Logging tools can be run in-hole. Wellbore, rock, and fluid information can be collected, which can later be processed and analyzed to estimate detailed reservoir properties such as permeability, porosity, saturations, and thickness. Petrophysical logs can provide the resolution needed to pick up localized features in the well or in the vicinity of the well. Logs can be the primary sources of most important and reliable data, providing a detailed description of the rock, fluid, and well. This information can be input to static geological models. In case a given subject well does not have petrophysical information, modelers can turn to other offset wells for petrophysical data for building the models.

PVT Data includes pressure, volume, and temperature data, which serve as reservoir fluid properties. A PVT analysis can include the process of determining the fluid behaviors and properties of oil, water, and gas samples from a reference well. Fluid samples for PVT analyses can be collected from a well during a drilling phase or a production phase of the well. The PVT data can also help in defining the phase behavior of reservoir fluids. Formation volume factors, viscosity, gas gravity, gas-oil ratio, and water salinity data can be used in a dynamic reservoir model. The PVT data use can be based on the number of phases (for example, two or three phases) in the reservoir.

A Reference Point is a depth at which all gauges are set to measure pressure data. The pressure at the reference point (for example, the gauge depth of the pressure measurement) can be required to initialize and simulate the pressure transient data in the transient model. Models can calculate simulated pressures at the reference point.

Relative Permeability refers to a concept used to enforce a preferential level of flow capacity due to the presence of multiple fluids at a given location in the reservoir. Relative Permeability can depend upon pore geometry, wettability, fluid distribution, and fluid saturation history. Relative permeability measurements can be conducted on core samples in a laboratory. Relative permeability measurements can be both time-consuming and expensive to produce.

As an example, in a single-phase fluid system, such as a dry gas or an under-saturated oil reservoir, the effective permeability of flow of the mobile fluid through the reservoir may vary a little during production because the fluid saturations do not change much. However, when more than one phase is mobile, the effective permeability to each mobile phase can change as the saturations of the fluids change in the reservoir. In the multiphase flow of fluids through porous media, the relative permeability of a phase can be a dimensionless measure of the effective permeability of that phase. The relative permeability can be represented as the ratio of the effective permeability of that phase to the absolute permeability. Relative permeability can be required for the calculation of permeability in each phase.

Reservoir Initial Conditions refer to the conditions when a well was drilled or before the well was subjected to any production or injection. The pressure and temperature data collected at that time is called the initial pressure and temperature of the reservoir. In addition, depths of the oil-water contact (OWC) and the gas-oil contact (GOC) need to be captured as well. These initial conditions can be utilized to build a hydro-dynamically balanced version of the transient model before the production and injection occur.

Well Control, Pressure-Transient Data, and Production Rates, when used in executing transient modeling, help to define well data in the well. In well control parameters, well history with reference to transient time can be defined. The production or injection history in different phases (for example, oil, water, or gas) separately can also be defined. The production or injection history can be required to match the pressure-transient data. Information for all flow, buildup, and fall-off periods of the wells can be defined in the data. Transient data of the measured pressures and production rates can be input into the transient model so that the information can be matched with the corresponding model predictions during simulation runs. The transient data of the measured pressures and the production rates can also help to accommodate any constraints. The constraints can be used, for example, to assure that well production rates and pressures do not go below or exceed certain limits during production or the shut-in phase. Constraints can be optional.

A Pressure Transient Analysis (PTA) well-test, also known as pressure transient testing or well testing, is a method used in reservoir engineering to evaluate the properties of a reservoir and assess the performance of a well. PTA involves measuring pressure changes in the wellbore or reservoir over time in response to controlled variations in production or injection rates. PTA provides valuable information about reservoir characteristics, including permeability, reservoir pressure, skin, and other parameters.

API gravity, or American Petroleum Institute gravity, is a scale that measures how heavy or light a petroleum liquid is relative to water. API gravity is the inverse of a petroleum liquid's density, and is calibrated in degrees API. A higher API gravity indicates a lighter compound, while a lower API gravity indicates a heavier compound. For example, crude oil typically has an API between 15 and 45 degrees. Liquids with an API greater than 10 are lighter and float on water, while liquids with an API less than 10 are heavier and sink.

The formation volume factor (Bo) is the ratio of the volume of a fluid phase at reservoir conditions to the volume of that same phase at surface conditions. It accounts for the shrinkage of oil volume as it moves from the reservoir to the surface. Bo is expressed in units of reservoir volume over standard volume (usually rbbl/STB).

A constant composition experiment (CCE), also known as a constant composition expansion (CCE) experiment, is a laboratory procedure used to determine the phase behavior of a mixture of hydrocarbons under varying pressure and temperature conditions while maintaining the composition of the mixture constant. In this experiment, a sample of a hydrocarbon mixture, typically representing a specific reservoir fluid or a synthetic mixture simulating such fluids, is placed in a high-pressure vessel. The composition of the mixture is controlled and maintained throughout the experiment. The constant composition experiment typically involves sample preparation, high-pressure vessel setup, pressure-temperature cycling, observation of phase behavior, and data analysis. Constant composition experiments are valuable tools for studying the phase behavior of reservoir fluids and predicting their behavior under reservoir conditions. The data obtained from these experiments are used to develop and validate equations of state, which are then incorporated into reservoir simulation models to predict reservoir performance and optimize production strategics. Additionally, constant composition experiments help in designing and optimizing processes for hydrocarbon recovery and processing.

A constant volume depletion (CVD) test, also known as Constant Volume Depletion Analysis (CVDA), is a laboratory experiment commonly used in the oil and gas industry to assess the reservoir fluid properties and estimate the amount of hydrocarbons that can be recovered from a reservoir under various pressure and temperature conditions. In a CVD test, a representative sample of reservoir fluid, typically obtained from a well during well testing or sampling operations, is placed in a fixed-volume vessel. The volume of the vessel remains constant throughout the test. The reservoir fluid sample is then subjected to controlled pressure and temperature conditions to simulate the conditions encountered in the reservoir. CVD tests provide valuable insights into the phase behavior, fluid properties, and reservoir performance of hydrocarbon fluids. The data obtained from these tests are used to calibrate reservoir simulation models, estimate recoverable reserves, optimize production strategies, and design production facilities in the oil and gas industry.

FIG. 1 illustrates an example of clustering a dataset including compositional measurements according to some implementations of the present disclosure. The present methodology for PVT-based reservoir fluid characterization generally involves several steps including: sampling, PVT analysis, fluid composition analysis, equation of state (EoS) analysis, fluid characterization, and reservoir simulation. During sampling, fluid samples may be collected from various locations at the reservoir, for example, through well testing or fluid sampling during drilling operations. In general, representative samples are collected that accurately reflect the fluid properties in the reservoir. The collected samples may then be subjected to laboratory PVT analysis, which can involve measuring various fluid properties such as pressure, volume, temperature, composition, and phase behavior under representative reservoir conditions. During fluid composition analysis, the composition of the fluid may be analyzed using techniques such as gas chromatography (GC), liquid chromatography (LC), or mass spectrometry (MS). The compositional analysis may help determine the components present in the fluid and their respective proportions. During equation of state (EoS) modeling, one or more EoS models may be developed to describe the thermodynamic behavior of the fluid based on the measured PVT data. The EoS model can then be used to calculate additional properties such as density, viscosity, compressibility, and phase behavior at different pressure and temperature conditions. During fluid characterization, the calculated fluid properties are used to characterize the reservoir fluid. The calculation may include determining the fluid type (oil, gas, or condensate), the API gravity of the oil, the gas-oil Ratio (GOR), the formation volume factor (Bo), and other relevant parameters. Thereafter, the characterized fluid properties may be incorporated into reservoir simulation models to accurately predict reservoir performance. Such enhanced simulation can facilitate reservoir management decisions, such as well placement, production forecasting, and optimizing production strategies. Notably, fluid characterization is an iterative and on-going process during which multiple analyses and simulations are often performed to refine the understanding of the reservoir fluid behavior. In this regard, advancements in technology and understanding of fluid behavior that give rise to additional measurement data can continue to shape and enhance PVT-based reservoir fluid characterization.

Some implementations may apply a machine learning (ML) methodology to a parent dataset for the purpose of segregation of the parent data into clusters. The basis of segregation is developed by the ML algorithm and may not be apparent to human senses. In the present disclosure, the parent dataset refers to fully developed data (also known as full records) based on existing characterization techniques. The full records are as detailed as possible in view of available techniques. For example, the full records are detailed for accounting for multiple data points from a formation, multiple data points from a field and multiple data points from a region. These data points can include results from compositional analysis, constant composition experiment (CCE), and constant volume depletion (CVD) tests. The segregation algorithm may function by clustering the full records into one or more clusters of data records.

Some implementations provide unique capabilities by clustering based on the features utilized for the segregation. For example, some implementations may focus on the following seven features of: concentration of C7+ (mol %), concentration of N₂ (mol %), concentration of CO₂ (mol %), concentration of H₂S (mol %), dryness defined as C1/(C1+C2+C3+C4+C5)]×100, wetness defined as [(C2+C3+C4+C5)/(C1+C2+C3+C4+C5)]×100, balance ratio defined as [(C1+C2)/(C3+C4+C5)], character ratio defined as (C4+C5)/C3, density of C7+, and molecular weight of C7+.

As illustrated in diagram 100 of FIG. 1, an example set of full records are clustered based on a singular feature, namely, dryness coefficient, to generate a multitude of clusters, namely, cluster/class 1 through 8.

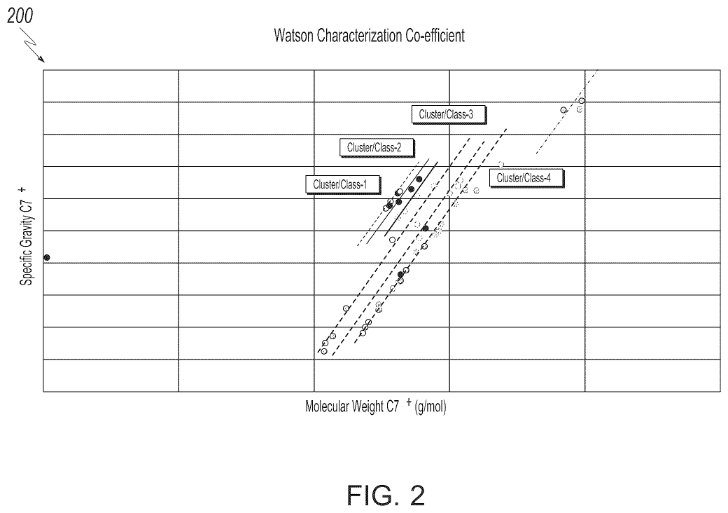

As illustrated in diagram 200 of FIG. 2, an example set of full records are clustered based on another singular feature, namely, Watson characterization coefficient, to generate a number of clusters, namely, cluster/class 1 through 4.

In both illustrations, each cluster is provided with at least one or more samples that have been fully characterized with compositional analysis, CCE. CVD and separator test lab data. As explained above, a thermodynamic model, for example, an equation of state (EoS) model, is developed based on the full complement of these results. The development of the thermodynamic model can take considerable time and significant tuning/validation. The thermodynamic model can represent the phase behavior of the petroleum fluid in the reservoir. The thermodynamic model may be used to predict the hydrocarbon fluid properties under the expected range of pressure and temperature covering the life of the reservoir and the whole production system. For example, the thermodynamic model be used to compute a wide array of properties of the petroleum fluid of the reservoir, such as gas-oil ratio (GOR) or condensate-gas ratio (CGR), density of each phase, volumetric factors and compressibility, and heat capacity and saturation pressure (bubble or dew point).

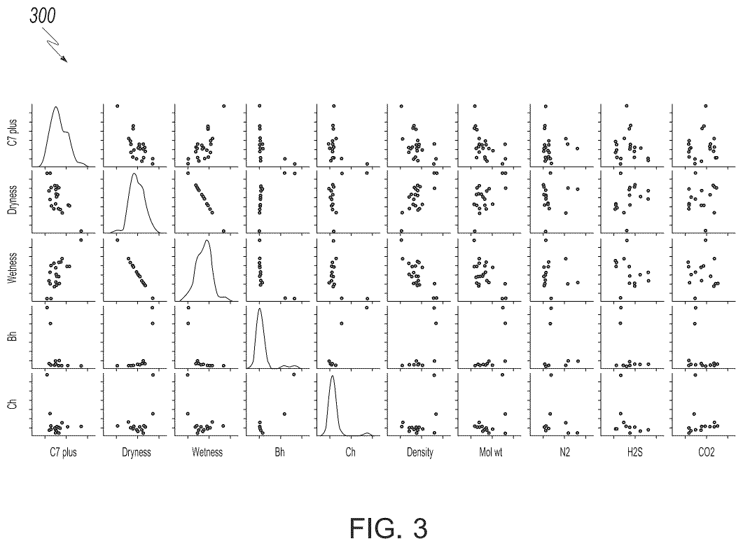

Significantly, the clustering operation performed by some implementations of the present disclosure involve correlating features that are multi-dimensional in nature (rather than a one-dimensional and singular parameter associated with FIGS. 1-2). For example, FIG. 3 is a chart illustrating an example of cross-correlating of at least four features from the compositional measurements, as used by some implementations of the present disclosure. Here, correlation is being examined amongst the following seven features: concentration of C7+ (mol %), concentration of N₂ (mol %), concentration of CO₂ (mol %), concentration of H₂S (mol %), dryness defined as C1/(C1+C2+C3+C4+C5)]×100, wetness defined as [(C2+C3+C4+C5)/(C1+C2+C3+C4+C5)]×100, balance ratio defined as [(C1+C2)/(C3+C4+C5)], character ratio defined as (C4+C5)/C3, density of (C7+), and molecular weight of C7+. Due to resolution challenges, FIG. 3 illustrates four (4) of the seven (7) features. Some implementations, however, can cover all seven (7) features.

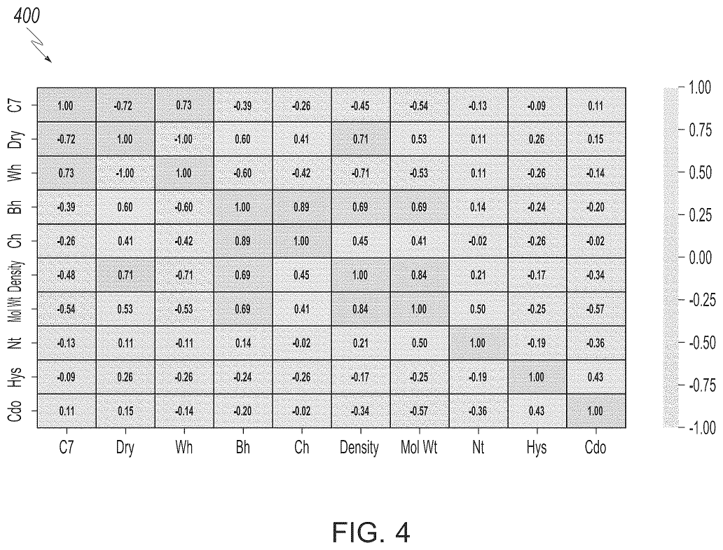

In another example, FIG. 4 is matrix illustrating the correlation coefficients between a total of ten (10) features from the compositional measurements, as used by some implementations of the present disclosure. Based on the correlation results, some implementations can segregate the child data (e.g., newly arrived partial records) into one or more clusters provided by the parent data (i.e., the full records). In some cases, the segregation can generate multiple clusters (also known as groups or buckets), each holding one or more data records. Significantly, when a child sample (also known as partial records which generally come from locations in the reservoir that are different the locations of the full records) is later identified by the segregation algorithm, then the thermodynamic model (e.g., an EoS model) of the parent sample (i.e., full records) can then be adjusted with the composition of the child sample to yield a corresponding thermodynamic model for the child sample (e.g., partial records), as explained above and further demonstrated below.

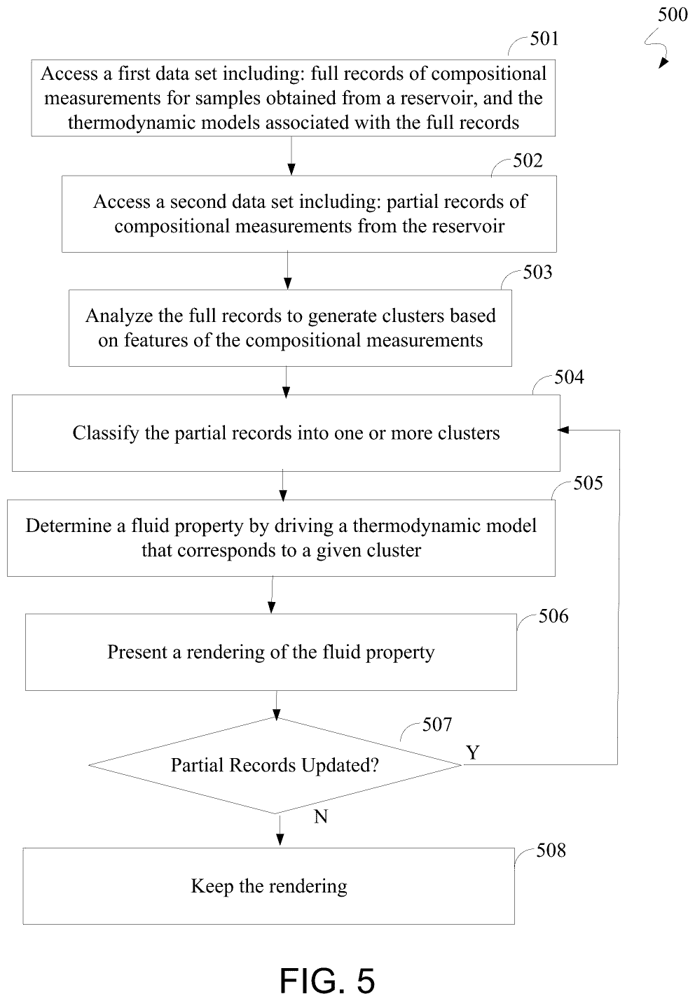

FIG. 5 shows an example of a flow chart 500 according to some implementations of the present disclosure. The illustrated process may access a first dataset that includes full records of PVT measurements for hydrocarbon fluid samples obtained from a first set of locations at a reservoir, as well as the thermodynamic models associated with the full records (501). The first dataset may also be known as the parent dataset that is based on existing characterization techniques and include detailed records including multiple data records from a formation, multiple data records from a field and multiple data records from a region. These data records generally include results from compositional analysis, constant composition experiment (CCE) and constant volume depletion (CVD) test results. Significantly, the parent dataset is developed along with the corresponding thermodynamic models (e.g., equation of state (EoS) models) developed using pressure-volume-temperature (PVT) data measured at the first set of locations at the reservoir.

The illustrated process may then access a second dataset including: partial records of compositional measurements of hydrocarbon fluid samples obtained from a second set of locations at the reservoir (502). The partial records may also be known as the second plurality of records. Significantly, the second plurality of records cover new samples obtained from a second set of locations at the reservoir that are different from the first set of locations. The new samples may be obtained after the EoS models have been developed. In some cases, the partial records may also be known as the child dataset that is without a developed thermodynamic model. While the child dataset may only include compositional measurements, implementations may leverage machine learning techniques to identify its equivalent parent dataset with the corresponding thermodynamic model, for example, an EoS model, which can then be applied to the child dataset to generate derived fluid properties, as further explained below.

The illustrated process may analyze, using a machine learning module, the first plurality of records of compositional measurements to generate a plurality of clusters (503). As revealed in FIGS. 1-2, the parent dataset can be clustered into several clusters each holding at least one data record. Each cluster may have its corresponding thermodynamic model (e.g., an EoS model). The clustering may be performed based on a multitude of features, rather than a single feature. The machine learning module may launch a KMeans algorithm to generate the plurality of clusters for the first plurality of records.

The illustrated process may classify, using the machine learning module, the second plurality of records of compositional measurements into one or more clusters generated from the first plurality of records of compositional measurements (504). The machine learning module may launch a decision tree algorithm to classify the second plurality of records of compositional measurements into the one or more clusters.

The illustrated process may determine a fluid property by driving a thermodynamic model that corresponds to a given cluster (505). For example, the illustrated process may drive a thermodynamic model from the plurality of thermodynamic models that corresponds to a given cluster of the one or more clusters to determine a fluid property of portions of the hydrocarbon fluid samples taken from the second set of locations at the reservoir. The portions of the hydrocarbon fluid correspond to portions of the second plurality of records classified into the given cluster. The fluid property comprises at least one of: a fluid type, a gravity measure of the hydrocarbon fluid sample, a gas-oil ratio (GOR), or a formation volume factor (Bo). The fluid type may include one of: oil, gas, or condensate. The gravity measure is the American Petroleum Institute (API) gravity. Here, hydrocarbon samples from the same origin are expected to fall within the same cluster. As such, if a new sample shares the same origin as the parent sample, then the attributes (such as the developed thermodynamic model) of the parent sample can be allocated to the new sample by virtue of the common origin.

The illustrated process may present a rendering of the fluid property (506). In some cases, once the composition of a child sample is acquired, the feature is used to identify the best representative cluster. Based on the identified cluster, the common EoS from that cluster can be used to predict the properties of the child sample. In the event that no clusters is identified, a full PVT assessment may be performed and this child sample can become a parent sample for a new cluster. In some implementations, the calculated fluid property may be tracked and results provided on, for example, a display device for visualization. The rendering may allow operators of the reservoir to monitor productivity at the reservoir. The rendering may also generate productivity predictions for operators of the reservoir. Because the thermodynamic model is developed once for the parent dataset, and not the child dataset, the implementation can achieve significant savings in computation time and memory usage, while achieving more realistic rendering of model-generated fluid properties for the production field of a reservoir.

The illustrated process may determine whether there are updates in the partial data records (507). In response to determining that the partial data records have been updated, the illustrated process may proceed to additional classification at block 504 so that the fluid property can be re-calculated based on thermodynamic models that correspond to a newly classified cluster. In response to determining no update in the partial data records, the illustrated process may keep the existing rendering of the calculated fluid property (508). In this manner, the illustrated process may provide iterative rendering in response to updates in the partial data records.

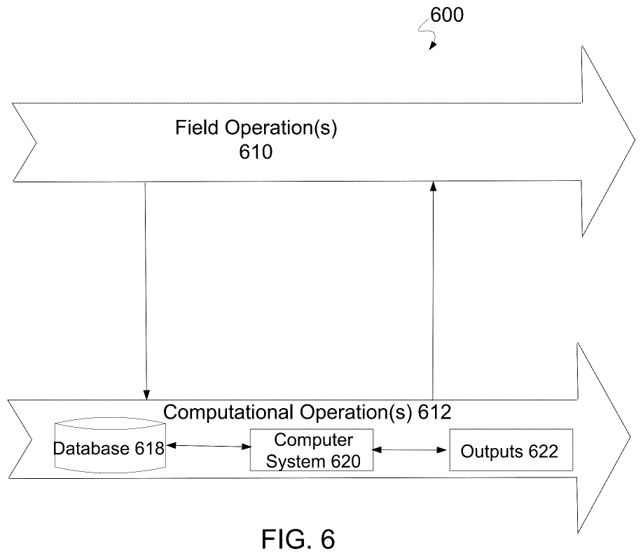

FIG. 6 illustrates hydrocarbon exploration and production operations 600 that include both one or more field operations 610 and one or more computational operations 612, which exchange information and control exploration for the exploration and production of hydrocarbons. In some implementations, outputs of techniques of the present disclosure can be performed before, during, or in combination with the hydrocarbon exploration and production operations 600, specifically, for example, either as field operations 610 or computational operations 612, or both.

Examples of field operations 610 include surveying operations, forming/drilling a wellbore, hydraulic fracturing, producing through the wellbore, injecting fluids (such as water) through the wellbore, to name a few. In some implementations, methods of the present disclosure can trigger or control the field operations 610. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 610 and responsively triggering the field operations 610 including, for example, generating plans and signals that provide feedback to and control physical components of the field operations 610. Alternatively or in addition, the field operations 610 can trigger the methods of the present disclosure. For example, implementing physical components (including, for example, hardware, such as sensors) deployed in the field operations 610 can generate plans and signals that can be provided as input or feedback (or both) to the methods of the present disclosure.

Examples of computational operations 612 include one or more computer systems 620 that include one or more processors and computer-readable media (e.g., non-transitory computer-readable media) operatively coupled to the one or more processors to execute computer operations to perform the methods of the present disclosure. A more detailed example can be found in FIG. 6. The computational operations 612 can be implemented using one or more databases 618, which store data received from the field operations 610 and/or generated internally within the computational operations 612 (e.g., by implementing the methods of the present disclosure) or both. For example, the one or more computer systems 620 process inputs from the field operations 610 to assess conditions in the physical world, the outputs of which are stored in the databases 618. For example, seismic sensors of the field operations 610 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 612 where they are stored in the databases 618 and analyzed by the one or more computer systems 620.

In some implementations, one or more outputs 622 generated by the one or more computer systems 620 can be provided as feedback/input to the field operations 610 (either as direct input or stored in the databases 618). The field operations 610 can use the feedback/input to control physical components used to perform the field operations 610 in the real world.

For example, the computational operations 612 can process the seismic data to generate three-dimensional (3D) maps of the subsurface formation. The computational operations 612 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 612 to process new information about the formation and control the drilling to adjust to the observed conditions in real-time.

The one or more computer systems 620 can update the 3D maps of the subsurface formation as information from one exploration well is received and the computational operations 612 can adjust the location of the next exploration well based on the updated 3D maps. Similarly, the data received from production operations can be used by the computational operations 612 to control components of the production operations. For example, production well and pipeline data can be analyzed to predict slugging in pipelines leading to a refinery and the computational operations 612 can control machine operated valves upstream of the refinery to reduce the likelihood of plant disruptions that run the risk of taking the plant offline.

In some implementations of the computational operations 612, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

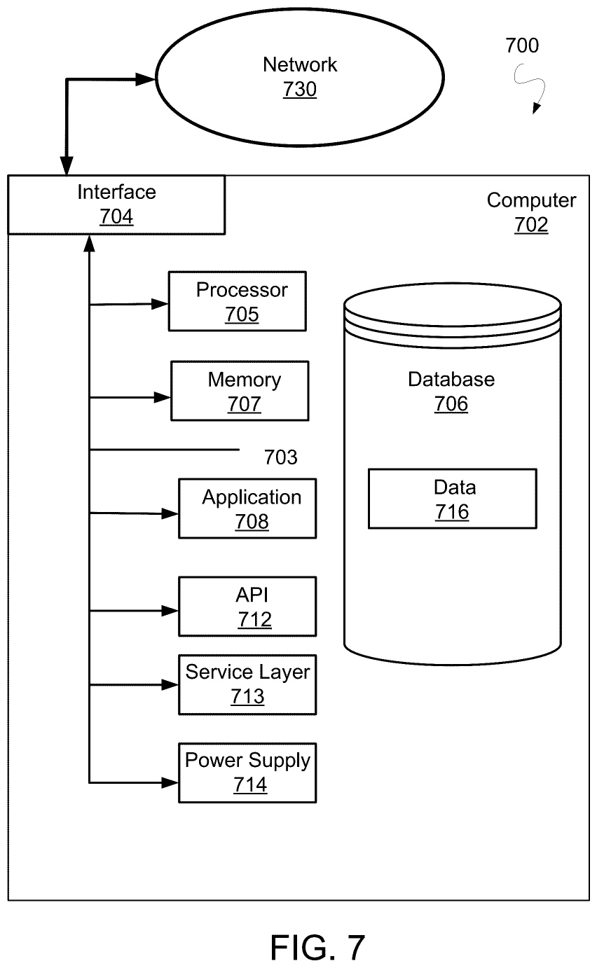

FIG. 7 is a block diagram illustrating an example of a computer system 700 used to provide computational functionalities associated with described algorithms, methods, functions, processes, flows, and procedures, according to an implementation of the present disclosure. The illustrated computer 702 is intended to encompass any computing device such as a server, desktop computer, laptop/notebook computer, wireless data port, smart phone, personal data assistant (PDA), tablet computing device, one or more processors within these devices, another computing device, or a combination of computing devices, including physical or virtual instances of the computing device, or a combination of physical or virtual instances of the computing device. Additionally, the computer 702 can comprise a computing device that includes an input device, such as a keypad, keyboard, touch screen, another input device, or a combination of input devices that can accept user information, and an output device that conveys information associated with the operation of the computer 702, including digital data, visual, audio, another type of information, or a combination of types of information, on a graphical-type user interface (UI) (or GUI) or other UI.

The computer 702 can serve in a role in a computer system as a client, network component, a server, a database or another persistency, another role, or a combination of roles for performing the subject matter described in the present disclosure. The illustrated computer 702 is communicably coupled with a network 730. In some implementations, one or more components of the computer 702 can be configured to operate within an environment, including cloud-computing-based, local, global, another environment, or a combination of environments.

The computer 702 is an electronic computing device operable to receive, transmit, process, store, or manage data and information associated with the described subject matter. According to some implementations, the computer 702 can also include or be communicably coupled with a server, including an application server, e-mail server, web server, caching server, streaming data server, another server, or a combination of servers.

The computer 702 can receive requests over network 730 (for example, from a client software application executing on another computer 702) and respond to the received requests by processing the received requests using a software application or a combination of software applications. In addition, requests can also be sent to the computer 702 from internal users, external or third-parties, or other entities, individuals, systems, or computers.

Each of the components of the computer 702 can communicate using a system bus 703. In some implementations, any or all of the components of the computer 702, including hardware, software, or a combination of hardware and software, can interface over the system bus 703 using an application programming interface (API) 712, a service layer 713, or a combination of the API 712 and service layer 713. The API 712 can include specifications for routines, data structures, and object classes. The API 712 can be either computer-language independent or dependent and refer to a complete interface, a single function, or even a set of APIs. The service layer 713 provides software services to the computer 702 or other components (whether illustrated or not) that are communicably coupled to the computer 702. The functionality of the computer 702 can be accessible for all service consumers using this service layer. Software services, such as those provided by the service layer 713, provide reusable, defined functionalities through a defined interface. For example, the interface can be software written in JAVA, C++, another computing language, or a combination of computing languages providing data in extensible markup language (XML) format, another format, or a combination of formats. While illustrated as an integrated component of the computer 702, alternative implementations can illustrate the API 712 or the service layer 713 as stand-alone components in relation to other components of the computer 702 or other components (whether illustrated or not) that are communicably coupled to the computer 702. Moreover, any or all parts of the API 712 or the service layer 713 can be implemented as a child or a sub-module of another software module, enterprise application, or hardware module without departing from the scope of the present disclosure.

The computer 702 includes an interface 704. Although illustrated as a single interface 704 in FIG. 7, two or more interfaces 704 can be used according to particular needs, desires, or particular implementations of the computer 702. The interface 704 is used by the computer 702 for communicating with another computing system (whether illustrated or not) that is communicatively linked to the network 730 in a distributed environment. Generally, the interface 704 is operable to communicate with the network 730 and comprises logic encoded in software, hardware, or a combination of software and hardware. More specifically, the interface 704 can comprise software supporting one or more communication protocols associated with communications such that the network 730 or interface's hardware is operable to communicate physical signals within and outside of the illustrated computer 702.

The computer 702 includes a processor 705. Although illustrated as a single processor 705 in FIG. 7, two or more processors can be used according to particular needs, desires, or particular implementations of the computer 702. Generally, the processor 705 executes instructions and manipulates data to perform the operations of the computer 702 and any algorithms, methods, functions, processes, flows, and procedures as described in the present disclosure.

The computer 702 also includes a database 706 that can hold data for the computer 702, another component communicatively linked to the network 730 (whether illustrated or not), or a combination of the computer 702 and another component. For example, database 706 can be an in-memory, conventional, or another type of database storing data consistent with the present disclosure. In some implementations, database 706 can be a combination of two or more different database types (for example, a hybrid in-memory and conventional database) according to particular needs, desires, or particular implementations of the computer 702 and the described functionality. Although illustrated as a single database 706 in FIG. 7, two or more databases of similar or differing types can be used according to particular needs, desires, or particular implementations of the computer 702 and the described functionality. While database 706 is illustrated as an integral component of the computer 702, in alternative implementations, database 706 can be external to the computer 702. As illustrated, the database 706 holds data 716 including, for example, parent dataset and child dataset, as well as data structures encoding thermodynamic models developed under the parent dataset, as explained in more detail in association with FIGS. 1-6.

The computer 702 also includes a memory 707 that can hold data for the computer 702, another component or components communicatively linked to the network 730 (whether illustrated or not), or a combination of the computer 702 and another component. Memory 707 can store any data consistent with the present disclosure. In some implementations, memory 707 can be a combination of two or more different types of memory (for example, a combination of semiconductor and magnetic storage) according to particular needs, desires, or particular implementations of the computer 702 and the described functionality. Although illustrated as a single memory 707 in FIG. 7, two or more memories 707 or similar or differing types can be used according to particular needs, desires, or particular implementations of the computer 702 and the described functionality. While memory 707 is illustrated as an integral component of the computer 702, in alternative implementations, memory 707 can be external to the computer 702.

The application 708 is an algorithmic software engine providing functionality according to particular needs, desires, or particular implementations of the computer 702, particularly with respect to functionality described in the present disclosure. For example, application 708 can serve as one or more components, modules, or applications. Further, although illustrated as a single application 708, the application 708 can be implemented as multiple applications 708 on the computer 702. In addition, although illustrated as integral to the computer 702, in alternative implementations, the application 708 can be external to the computer 702.

The computer 702 can also include a power supply 714. The power supply 714 can include a rechargeable or non-rechargeable battery that can be configured to be either user- or non-user-replaceable. In some implementations, the power supply 714 can include power-conversion or management circuits (including recharging, standby, or another power management functionality). In some implementations, the power-supply 714 can include a power plug to allow the computer 702 to be plugged into a wall socket or another power source to, for example, power the computer 702 or recharge a rechargeable battery.

There can be any number of computers 702 associated with, or external to, a computer system containing computer 702, each computer 702 communicating over network 730. Further, the term “client,” “user,” or other appropriate terminology can be used interchangeably, as appropriate, without departing from the scope of the present disclosure. Moreover, the present disclosure contemplates that many users can use one computer 702, or that one user can use multiple computers 702.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal, for example, a machine-generated electrical, optical, or electromagnetic signal that is generated to encode information for transmission to a receiver apparatus for execution by a data processing apparatus. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” or “electronic computer device” (or equivalent as understood by one of ordinary skill in the art) refer to data processing hardware and encompass all kinds of apparatus, devices, and machines for processing data, including by way of example, a programmable processor, a computer, or multiple processors or computers. The apparatus can also be, or further include special purpose logic circuitry, for example, a central processing unit (CPU), an FPGA (field programmable gate array), or an ASIC (application-specific integrated circuit). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with an operating system of some type, for example LINUX, UNIX, WINDOWS, MAC OS, ANDROID, IOS, another operating system, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and apparatus can also be implemented as, special purpose logic circuitry, for example, a CPU, an FPGA, or an ASIC.

Computers for the execution of a computer program can be based on general or special purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device.

Non-transitory computer-readable media for storing computer program instructions and data can include all forms of media and memory devices, magnetic devices, magneto optical disks, and optical memory device. Memory devices include semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Magnetic devices include, for example, tape, cartridges, cassettes, internal/removable disks. Optical memory devices include, for example, digital video disc (DVD), CD-ROM, DVD+/−R, DVD-RAM, DVD-ROM, HD-DVD, and BLURAY, and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special purpose logic circuitry.

To provide for interaction with a user, implementations of the subject matter described in this specification can be implemented on a computer having a display device, for example, a CRT (cathode ray tube), LCD (liquid crystal display), LED (Light Emitting Diode), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity, a multi-touch screen using capacitive or electric sensing, or another type of touchscreen. Other types of devices can be used to interact with the user. For example, feedback provided to the user can be any form of sensory feedback. Input from the user can be received in any form, including acoustic, speech, or tactile input. In addition, a computer can interact with the user by sending documents to and receiving documents from a client computing device that is used by the user.

The term “graphical user interface,” or “GUI,” can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11 a/b/g/n or 802.20 (or a combination of 802.11x and 802.20 or other protocols consistent with the present disclosure), all or a portion of the Internet, another communication network, or a combination of communication networks. The communication network can communicate with, for example, Internet Protocol (IP) packets, Frame Relay frames, Asynchronous Transfer Mode (ATM) cells, voice, video, data, or other information between networks addresses.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

What is claimed is:

1. A computer-implemented method comprising:
accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements;
accessing a second dataset comprising a second plurality of records of compositional measurements for hydrocarbon fluid samples obtained from a second set of locations at the reservoir;
analyzing, using a machine learning module, the first plurality of records of compositional measurements to generate a plurality of clusters;
classifying, using the machine learning module, the second plurality of records of compositional measurements into one or more clusters from the plurality of clusters;
driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and
presenting a rendering of the fluid property as the second dataset expands.

2. The computer-implemented method of claim 1, wherein the rendering is presented iteratively with each update of additional records from the second dataset.

3. The computer-implemented method of claim 1, wherein the plurality of thermodynamic models comprises at least one equation of state (EoS) model.

4. The computer-implemented method of claim 1, wherein the fluid property comprises at least one of: a fluid type, a gravity measure of an underlying hydrocarbon fluid sample, a gas-oil ratio (GOR), or a formation volume factor (Bo),
wherein the fluid type comprises one of: oil, gas, or condensate,
wherein the gravity measure is the American Petroleum Institute (API) gravity.

5. The computer-implemented method of claim 1, wherein the machine learning module launches a KMeans algorithm to generate the plurality of clusters.

6. The computer-implemented method of claim 1, wherein the machine learning module launches a decision tree algorithm to classify the second plurality of records of compositional measurements into the one or more clusters.

7. The computer-implemented method of claim 1, wherein the first set of locations and the second set of locations are not identical.

8. One or more computer-readable storage media encoded with instructions that, when executed by one or more computers, cause the one or more computers to perform operations of:
accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements;
accessing a second dataset comprising a second plurality of records of compositional measurements for hydrocarbon fluid samples obtained from a second set of locations at the reservoir;
analyzing, using a machine learning module, the first plurality of records of compositional measurements to generate a plurality of clusters;
classifying, using the machine learning module, the second plurality of records of compositional measurements into one or more clusters from the plurality of clusters;
driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and
presenting a rendering of the fluid property as the second dataset expands.

9. The one or more computer-readable storage media of claim 8, wherein the rendering is presented iteratively with each update of additional records from the second dataset.

10. The one or more computer-readable storage media of claim 8, wherein the plurality of thermodynamic models comprises at least one equation of state (EoS) model.

11. The one or more computer-readable storage media of claim 8, wherein the fluid property comprises at least one of: a fluid type, a gravity measure of the hydrocarbon fluid sample, a gas-oil ratio (GOR), or a formation volume factor (Bo),
wherein the fluid type comprises one of: oil, gas, or condensate,
wherein the gravity measure is the American Petroleum Institute (API) gravity.

12. The one or more computer-readable storage media of claim 8, wherein the machine learning module is configured to operate a KMeans algorithm to generate the plurality of clusters.

13. The one or more computer-readable storage media of claim 8, wherein the machine learning module is configured to operate a decision tree algorithm to classify the second plurality of records of compositional measurements into the one or more clusters.

14. The one or more computer-readable storage media of claim 8, wherein the first set of locations and the second set of locations are not identical.

15. A computer system comprising one or more computer processors configured to perform operations of:
accessing a first dataset comprising: (i) a first plurality of records of compositional measurements for hydrocarbon fluid samples obtained from a first set of locations at a reservoir, and (ii) a data structure encoding a plurality of thermodynamic models developed using pressure-volume-temperature (PVT) data measured at the first set of locations at the reservoir and the first plurality of records of compositional measurements;
accessing a second dataset comprising a second plurality of records of compositional measurements for hydrocarbon fluid samples obtained from a second set of locations at the reservoir;
analyzing, using a machine learning module, the first plurality of records of compositional measurements to generate a plurality of clusters;
classifying, using the machine learning module, the second plurality of records of compositional measurements into one or more clusters from the plurality of clusters;
driving a thermodynamic model from the plurality of thermodynamic models that corresponds to a given cluster of the one or more clusters to determine a fluid property of portions of the hydrocarbon fluid samples taken from the second set of locations at the reservoir, wherein the portions of the hydrocarbon fluid correspond to portions of the second plurality of records classified into the given cluster; and
presenting a rendering of the fluid property as the second dataset expands.

16. The computer system of claim 15, wherein the rendering is presented iteratively with each update of additional records from the second dataset.

17. The computer system of claim 15, wherein the plurality of thermodynamic models comprises at least one equation of state (EoS) model.

18. The computer system of claim 15, wherein the fluid property comprises at least one of: a fluid type, a gravity measure of the hydrocarbon fluid sample, a gas-oil ratio (GOR), or a formation volume factor (Bo),
wherein the fluid type comprises one of: oil, gas, or condensate,
wherein the gravity measure is the American Petroleum Institute (API) gravity.

19. The computer system of claim 15, wherein the machine learning module is configured to operate a KMeans algorithm to generate the plurality of clusters.

20. The computer system of claim 15, wherein the machine learning module is configured to operate a decision tree algorithm to classify the second plurality of records of compositional measurements into the one or more clusters, and
wherein the first set of locations and the second set of locations are not identical.
